(19) United States
(12) Patent Application Publication
(10) Pub. No.: US 2021/0313439 A1
(43) Pub. Date: Oct. 7, 2021

(54) ELECTRONIC DEVICE INCLUDING FERROELECTRIC LAYER AND METHOD OF MANUFACTURING THE SAME

(71) Applicant: Samsung Electronics Co., Ltd., Suwon-si (KR)

(72) Inventors: Kwanghee LEE, Hwaseong-si (KR); Sangwook KIM, Seongnam-si (KR); Seunggeol NAM, Suwon-si (KR); Taehwan MOON, Suwon-si (KR); Yunseong LEE, Osan-si (KR); Sanghyun JO, Seoul (KR); Jinseong HEO, Seoul (KR)

(73) Assignee: Samsung Electronics Co., Ltd., Suwon-si (KR)

(21) Appl. No.: 17/119,337

(22) Filed: Dec. 11, 2020

(30) Foreign Application Priority Data
Apr. 7, 2020 (KR) 10-2020-0042412

(51) Int. Cl. H01L 29/49; H01L 29/786; H01L 29/78; H01L 29/66; H01L 29/40

(52) U.S. Cl. CPC H01L 29/4908; H01L 29/7869; H01L 29/401; H01L 29/66969; H01L 29/78391

(57) ABSTRACT

Disclosed herein is an electronic device including: a lower gate electrode; a ferroelectric layer covering the lower gate electrode; a first insertion layer covering the ferroelectric layer and including a dielectric material; a channel layer provided on the first insertion layer, at a position corresponding to the lower gate electrode, the channel layer including an oxide semiconductor material; and a source electrode and a drain electrode formed to be electrically connected to both ends of the channel layer, respectively.

### CROSS-REFERENCE TO RELATED APPLICATION

This application claims the benefit of Korean Patent Application No. 10-2020-0042412, filed on Apr. 7, 2020, in the Korean Intellectual Property Office, the disclosure of which is incorporated herein in its entirety by reference.

### BACKGROUND

### 1. Field

The present disclosure relates to an electronic device including a ferroelectric layer and a method of manufacturing the electronic device.

### 2. Description of Related Art

With the down-scaling of integrated circuit devices, the space occupied by electronic devices such as transistors and capacitors has been rapidly reduced. As the spatial dimensions of the electronic devices are reduced the operational characteristics of the electronic device may also be affected due to limitations in the characteristics of the materials included in the electronic devices. Hafnium oxide (HfO₂) materials capable of overcoming these spatial limitations and exhibiting good operating characteristics, have recently been used to realize ferroelectricity.

Together with an additional element, such as Zr, HfO₂ may exhibit ferroelectricity having a negative capacitance effect. HfO₂ may also reduce power consumption of electronic devices used as transistors for logic devices and transistors for memory devices.

Meanwhile, many methods have been proposed for applying a ferroelectric layer as a gate insulating film (gate insulator) to an oxide semiconductor transistor, which is in the spotlight due to its advantages of a low-temperature process and low leakage current, to utilize the oxide semiconductor transistor as a logic and/or memory device. In this case, a material optimized by controlling the multiple combinations and composition ratios of In, Ga, Zn, Si, and Sn is adopted as the oxide semiconductor material used as a channel material. When a ferroelectric material is used as the gate insulating film, since oxygen atoms present in both the channel and the gate insulating film have different binding energies, an interaction may occur between the semiconductor channel layer and the gate insulating film during a subsequent annealing process to align the polarization direction of the gate insulating film, and this interaction between the semiconductor channel layer and the gate insulating film may deteriorate the characteristics of transistors.

### SUMMARY

Provided are electronic devices each having a structure capable of suppressing and/or preventing an interaction between a ferroelectric layer and a channel layer including an oxide semiconductor material.

Provided are methods of manufacturing an electronic device in which ferroelectricity of a ferroelectric layer included in the electronic device may be enhanced and a process cost may be reduced.

Additional aspects will be set forth in part in the description which follows and, in part, will be apparent from the description, or may be learned by practice of the presented embodiments of the disclosure.

According to an aspect of an example embodiment, an electronic device may include: a lower gate electrode; a ferroelectric layer covering the lower gate electrode; a first insertion layer covering the ferroelectric layer, the first insertion layer including a dielectric material; a channel layer on the first insertion layer, at a position corresponding to the lower gate electrode, the channel layer including an oxide semiconductor material; and a source electrode electrically connected to a first end of the channel layer and a drain electrode electrically connected to a second end of the channel layer, respectively.

The first insertion layer may be thinner than the ferroelectric layer.

The first insertion layer may have a thickness of about 0.3 nm to about 3 nm.

A thermal expansion coefficient of the first insertion layer may be different from a thermal expansion coefficient of the ferroelectric layer.

The first insertion layer may include at least one of Al₂O₃, SiOₓ, AlOₓ, SiON, SiN, and a combination thereof.

The first insertion layer may include a dopant. The dopant may be at least one of Si, Al, Zr, Y, La, Gd, Sr, Hf, and Ce.

The oxide semiconductor material may include at least one of ZnSnO, InGaO, InZnO, InGaZnO, InSnO, InSnZnO, and InSnGaO.

The ferroelectric layer may include an oxide-based dielectric. The ferroelectric layer may include at least one of HfO, ZrO, SiO, AlO, CeO, YO, LaO, and a perovskite structure compound. For example, the ferroelectric layer may include a HfO₂-based dielectric material.

The ferroelectric layer may include a domain under the channel layer with a polarization alignment different from another domain of the ferroelectric layer.

The electronic device may further include: a second insertion layer provided between the lower gate electrode and the ferroelectric layer. The second insertion layer may include a dielectric material.

The second insertion layer may be thinner than the ferroelectric layer.

The second insertion layer may have a thickness of about 0.3 nm to about 3 nm.

According to an aspect of another example embodiment, an electronic device may include: a channel layer including an oxide semiconductor material; a source electrode and a drain electrode electrically connected to a first end of the channel layer and a second end of the channel layer, respectively; a first insertion layer covering the channel layer, the first insertion layer including a dielectric material; a ferroelectric layer covering the first insertion layer; and a gate electrode covering the ferroelectric layer.

The first insertion layer may be thinner than the ferroelectric layer.

The first insertion layer may have a thickness of about 0.3 nm to about 3 nm.

The electronic device may further include: a second insertion layer provided between the ferroelectric layer and the gate electrode and including a dielectric material.

The second insertion layer may be thinner than the ferroelectric layer.

The second insertion layer has a thickness of about 0.3 nm to about 3 nm.

According to an aspect of another example embodiment, a method of manufacturing an electronic device may include: forming a lower gate electrode on a substrate; continuously forming a ferroelectric layer and a first insertion layer, the ferroelectric layer covering the lower gate electrode and the first insertion layer covering the ferroelectric layer, the first insertion layer including a dielectric material; forming a channel layer the first insertion layer at a position corresponding to the lower gate electrode, the channel layer including an oxide semiconductor material on; and forming a source electrode and a drain electrode to be electrically connected to a first end and a second end of the channel layer, respectively.

In the continuous forming of the ferroelectric layer and the first insertion layer, the ferroelectric layer and the first insertion layer may be continuously formed in the same chamber without changing formation conditions.

The first insertion layer may be formed to have a thickness of about 0.3 nm to about 3 nm.

The method may further include forming a second insertion layer before the ferroelectric layer, the second insertion layer covering the lower gate electrode and including a dielectric material, wherein the second insertion layer, the ferroelectric layer, and the first insertion layer are sequentially and continuously formed.

According to an aspect of another embodiment, a method of manufacturing an electronic device may include: forming, on a substrate, a channel layer including an oxide semiconductor material and a source electrode and a drain electrode electrically connected to a first end and a second end of the channel layer, respectively; continuously forming a first insertion layer and a ferroelectric layer, the insertion layer covering the channel layer and including a dielectric material and the ferroelectric layer covering the first insertion layer; and forming a gate electrode covering the ferroelectric layer.

In the continuously forming the first insertion layer and the ferroelectric layer, the first insertion layer and the ferroelectric layer may be continuously formed in the same chamber without changing formation conditions.

The first insertion layer may be formed to have a thickness of about 0.3 nm to about 3 nm.

The method may further include forming a second insertion layer covering the ferroelectric layer before forming the gate electrode, the second insertion layer including a dielectric material, wherein the first insertion layer, the ferroelectric layer, and the second insertion layer are sequentially and continuously formed.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a side cross-sectional view schematically illustrating a configuration of an electronic device according to an example embodiment;

FIG. 2 is a side cross-sectional view schematically illustrating a configuration of an electronic device according to a comparative example;

FIG. 3 is a graph schematically illustrating voltage-current characteristics of the electronic device of FIG. 2;

FIG. 4 is a graph schematically illustrating voltage-current characteristics of the electronic device of FIG. 1 having a first insertion layer of 0.5 nm;

FIG. 5 is a graph schematically illustrating voltage-current characteristics of the electronic device of FIG. 1 having a first insertion layer of 1 nm;

FIG. 6 is a side cross-sectional view schematically illustrating a configuration of an electronic device according to another example embodiment;

FIGS. 7A and 7B are side cross-sectional views schematically illustrating configurations of electronic devices according to some example embodiment;

FIG. 8 is a side cross-sectional view schematically illustrating a configuration of an electronic device according to another example embodiment;

FIGS. 9 to 11 are side cross-sectional views schematically illustrating the procedure of a method of manufacturing an electronic device according to an example embodiment;

FIGS. 12 to 14 are side cross-sectional views schematically illustrating the procedure of a method of manufacturing an electronic device according to an example embodiment;

FIGS. 15 to 17 are side cross-sectional views schematically illustrating the procedure of a method of manufacturing an electronic device according to an example embodiment;

FIGS. 18 to 20 are side cross-sectional views schematically illustrating the procedure of a method of manufacturing an electronic device according to an example embodiment; and

FIG. 21 shows a schematic of a circuit device that may include the aforementioned semiconductor devices according to some example embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, electronic devices each including a ferroelectric layer and methods of manufacturing the electronic devices according to embodiments will be described with reference to the attached drawings. In the following drawings, the same reference numerals refer to the same components, and the size or thickness of each component may be exaggerated for clarity and convenience. Meanwhile, embodiments to be described below are merely exemplary, and various modifications are possible from these embodiments.

Hereinafter, what is described as “on” or “over” may include not only that which is directly above in contact, but also that which is above in a non-contact manner. As used herein, the singular forms “a”, “an” and “the” are intended to include the plural forms as well, unless the context clearly indicates otherwise. When a part is said to “include” a component, this means that other components may be further included instead of excluding other components, unless otherwise stated.

The use of the term “above-described” and similar indication terms may correspond to both singular and plural. Unless explicitly stated or contrary to steps constituting a method, the steps may be performed in a suitable order. It is not necessarily limited to the order of description of the above steps.

Although the terms “first”, “second”, etc., may be used herein to describe various elements, components, regions, and/or layers, these elements, components, regions, and/or layers should not be limited by these terms. These terms are used only to distinguish one component from another, not for purposes of limitation. Electronic devices each including a ferroelectric layer and methods of manufacturing the electronic devices can be implemented in various different forms and are not limited to the embodiments described herein.

When the terms “about” or “substantially” are used in this specification in connection with a numerical value and/or composition, it is intended that the associated numerical value includes a manufacturing tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values, compositions, or shapes are modified as “about” or “substantially,” it will be understood that these values, compositions, and shapes should be construed as including a manufacturing or operational tolerance (e.g., ±10%) around the stated numerical values, compositions, and/or shapes.

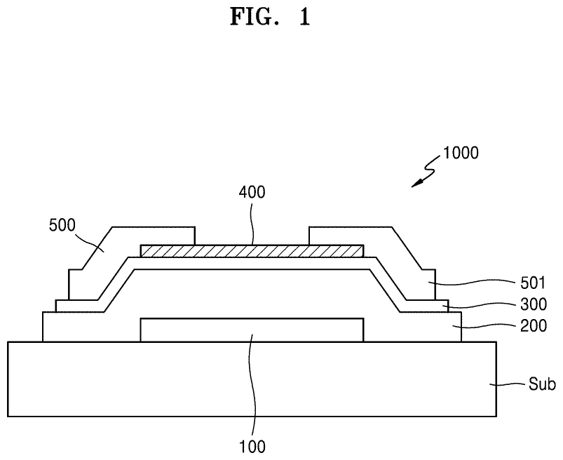

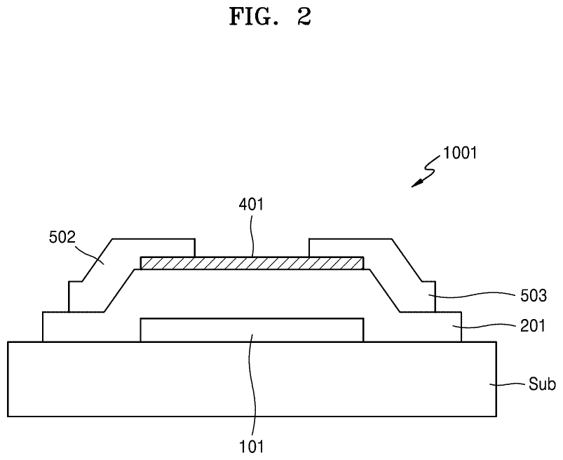

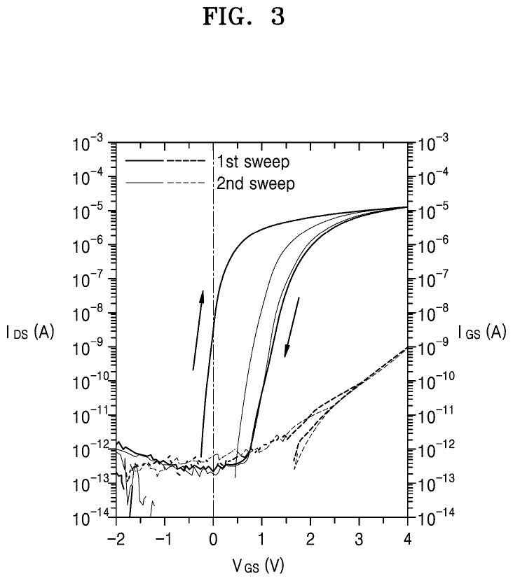

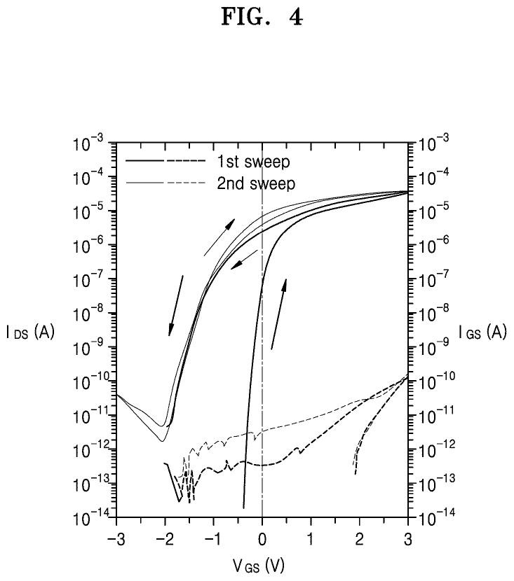

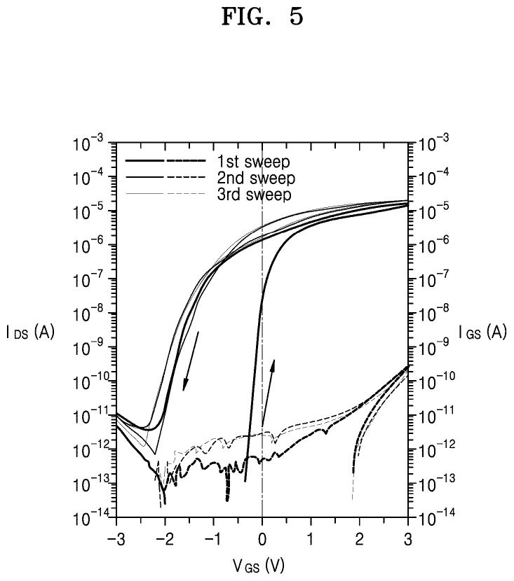

FIG. 1 is a side cross-sectional view schematically illustrating the configuration of an electronic device 1000 according to an example embodiment. FIG. 2 is a side cross-sectional view schematically illustrating the configuration of an electronic device 1001 according to a comparative example. FIG. 3 is a graph schematically illustrating the voltage-current characteristics of the electronic device 1001 of FIG. 2. FIG. 4 is a graph schematically illustrating the voltage-current characteristics of the electronic device 1000 of FIG. 1 having a first insertion layer 300 of 0.5 nm. FIG. 5 is a graph schematically illustrating the voltage-current characteristics of the electronic device 1000 of FIG. 1 having a first insertion layer 300 of 1 nm. The graphs of FIGS. 4 and 5 to illustrate the voltage-current characteristics of the electronic device 1000 wherein the first insertion layer 300 includes AlOx. The graphs of FIGS. 3 to 5 illustrate the voltage-current characteristics of the electronic device 1000, 1001 including 10 nm ferroelectric layer 200, 201 including HZO.

Referring to FIG. 1, the electronic device 1000 may include: a lower gate electrode 100; a ferroelectric layer 200 covering the lower gate electrode 100; a first insertion layer 300 covering the ferroelectric layer 200 and including a dielectric material; a channel layer 400 provided at a position corresponding to the lower gate electrode 100 on the first insertion layer 300 and including an oxide semiconductor material; and a source electrode 500 and a drain electrode 501 electrically connected to both ends of the channel layer 400, respectively. The electronic device 1000 may be on a substrate Sub. For example, the lower gate electrode 100 may be provided on the substrate Sub. Moreover, a part of the ferroelectric layer 200 covering the lower gate electrode 100 may also contact the substrate Sub. This electronic device 1000 may be referred to as a bottom gate type transistor.

The substrate Sub may be a semiconductor substrate or an insulating substrate. For example, the substrate Sub may include various semiconductor substrate each including silicon, silicon carbide, germanium, silicon-germanium, and/or group III-V semiconductor materials. In another example, the substrate Sub may include an insulating substrate such as a sapphire substrate. However, the material of the substrate Sub is not so limited, and may be variously changed.

The lower gate electrode 100 may include a conductive material like metal material such as molybdenum (Mo), titanium (Ti), tantalum (Ta), tungsten (W), aluminum (Al), copper (Cu), neodymium (Nd), and/or scandium (Sc). In addition, the lower gate electrode 100 may be include nitride of the aforementioned metal material, and/or may include an alloy material including the aforementioned metal material as a main ingredient. However, the material of the lower gate electrode 100 is not limited thereto, and the lower gate electrode 100 may include a conductive material other than the metal materials listed above. The lower gate electrode 100 may be formed in a single-layer structure or a stacked structure.

The ferroelectric layer 200 may include a dielectric thin film including a dielectric material. The dielectric thin film may be based on HfO₂ and may exhibit ferroelectricity depending on the crystal phase of the thin film. The ferroelectric layer 200 may include a material in which a dopant is added to the dielectric material. The dopants may include at least one of silicon (Si), aluminum (Al), zirconium (Zr), yttrium (Y), lanthanum (La), gadolinium (Gd), strontium (Sr), Hf, and/or cerium (Ce). However, the present invention is not limited thereto, and the type of dopant may include materials other than those listed above.

The ferroelectric layer 200 may include, for example, HfₓZr₍₁₋ₓ₎O (0<x<1). However, the present invention is not limited thereto, and the ferroelectric layer 200 may include at least one of HfO, ZrO, SiO, AIO, CeO, YO, LaO, and/or a perovskite structure compound. Moreover, the ferroelectric layer 200 may be formed of a material in which a dopant such as Si, Al, Zr, Y, La, Gd, Sr, Hf, and/or Ce is added to the at least one of HfO, ZrO, SiO, AlO, CeO, YO, LaO, and/or perovskite structure compound. However, the present invention is not limited thereto, and the type of dopant may include materials other than those listed above.

The ferroelectricity of the ferroelectric layer 200 varies according to a detailed crystalline phase represented by the material included in the ferroelectric layer 200. The reason for this is that a material composition, including the chemical composition, included in the ferroelectric layer 200 may influence the crystal structure. Therefore, it is possible to control the characteristics of the ferroelectric layer 200 in detail by adjusting the type and content of the dopant added to the ferroelectric layer 200. The ferroelectric layer 200 may be formed by an atomic layer deposition (ALD) process.

The first insertion layer 300 may include a dielectric material. For example, the first insertion layer 300 may include at least one of Al₂O₃, SiOₓ, AlOₓ, SiON, SiN, or a combination thereof. For example, the first insertion layer 300 may include SiO and/or AlO. The first insertion layer 300 may include a dopant such as Si, Al, Zr, Y, La, Gd, Sr, Hf, and/or Ce. However, the present invention is not limited thereto. For example the type of dopant may include materials other than those listed above, and the first insertion layer 300 may include a dielectric material having insulating properties in addition to the materials listed above.

The thickness of the first insertion layer 300 may be equal to the thickness of the ferroelectric layer 200. Alternatively, the first insertion layer 300 may be thinner than the ferroelectric layer 200. For example, the thickness of the first insertion layer 300 may be about 0.3 nm to about 3 nm.

The thermal expansion coefficient of the first insertion layer 300 may be different from the thermal expansion coefficient of the ferroelectric layer 200. Like this, when a structure including the first insertion layer 300 and the ferroelectric layer 200 having different thermal expansion coefficients is heated, stress based on the difference in thermal expansion coefficient may be applied to the ferroelectric layer 200 at high temperature. The stress may, for example, align the polarization of the crystalline and/or polycrystalline structure of the ferroelectric layer 200. In this case, the polarization arrangement of the ferroelectric layer 200 is further improved, and domains having the same polarization direction may be formed. For example, a domain of the ferroelectric layer 200 under the channel layer 400 may be compressed by the different thermal expansion coefficients at high temperature, creating a domain of the ferroelectric layer 200 under the channel layer 400 with a different polarization alignment than other domains of the ferroelectric layer 200.

The channel layer 400 may include an oxide semiconductor material. For example, the channel layer 400 may include at least one of Ga, Sn, Zn, Al, Mg, Hf, and a lanthanide. For example, the channel layer 400 may include at least one of quaternary metal oxides such as In—Sn—Ga—Zn—O-based materials; ternary metal oxides such as In—Ga—Zn—O-based materials, In—Sn—Zn—O-based materials, In—Sn—Ga—O-based materials, In—Al—Zn—O-based materials, Sn—Ga—Zn—O-based materials, Al—Ga—Zn—O-based materials, Sn—Al—Zn—O-based materials, In—Hf—Zn—O-based materials, In—La—Zn—O-based materials, In—Ce—Zn—O-based materials, In—Pr—Zn—O-based materials, In—Nb—Zn—O-based materials, In—Pm—Zn—O-based materials, In—Sm—Zn—O-based materials, In—Eu—Zn—O-based materials, In—Gd—Zn—O based materials, In—Er—Zn—O-based materials, In—Tm—Zn—O-based materials, In—Yb—Zn—O-based materials, and In—Lu—Zn—O-based materials; binary metal oxides such as In—Sn—O-based materials, In—Zn—O-based materials, Sn—Zn—O-based materials, Al—Zn—O-based materials, Zn—Mg—O-based materials, Sn—Mg—O System-based materials, In—Mg—O-based materials, and In—Ga—O-based materials; and one-component metal oxides such as In—O-based materials, Sn—O-based materials, and Zn—O-based materials. Here, for example, the In—Ga—Zn—O-based material means an oxide including indium (In), gallium (Ga), and zinc (Zn), and there is no particular limitation in the composition ratio thereof. In addition, the In—Ga—Zn—O-based oxide semiconductor may include elements different from In, Ga and Zn. InSnO may be referred to as ITO, InSnZnO may be referred to as ITZO, and InSnGaO may be referred to as ITGO.

The source electrode 500 and the drain electrode 501 may be electrically connected to a first end and a second end of the channel layer 400, respectively. For example, the source electrode 500 and the drain electrode 501 may be in contact with both ends of the channel layer 400, respectively. The source electrode 500 and the drain electrode 501 may include a conductive material. For example, the source electrode 500 and the drain electrode 501 may include at least one of Al, Cr, Cu, Ta, Ti, Mo, and/or W. Further, the source electrode 500 and the drain electrode 501 may include nitride of the above conductive material. Furthermore, the source electrode 500 and the drain electrode 501 may include a conductive metal oxide. Examples of the conductive metal oxide may include indium oxide (In₂O₃), tin oxide (SnO₂), zinc oxide (ZnO), an indium oxide-tin oxide alloy (In₂O₃—SnO₂, abbreviated as ITO), and an indium oxide-zinc oxide alloy (In₂O₃—ZnO).

As such, the electronic device 1000 may include a structure in which the first insertion layer 300 is provided on the ferroelectric layer 200. As described above, the thermal expansion coefficients of the ferroelectric layer 200 and the first insertion layer 300 may be different from each other. In this case, in the process of manufacturing the electronic device 1000, when the ferroelectric layer 200 and the first insertion layer 300 are deposited and then subjected to post deposition annealing (PDA), energy based on stress due to a difference in thermal expansion coefficient between the two layers may be applied to the ferroelectric layer 200 at high temperature. Accordingly, the polarization arrangement of the ferroelectric layer 200 may be controlled to maximize the remnant polarization (Pr) of the ferroelectric layer 200.

Referring to FIG. 2, the electronic device 1001 according to a comparative example may include: a lower gate electrode 101; a ferroelectric layer 201 covering the lower gate electrode 101; a channel layer 401 at a position corresponding to the lower gate electrode 101 on the ferroelectric layer 201 and including an oxide semiconductor material; and a source electrode 502 and a drain electrode 503 electrically connected to both ends of the channel layer 401, respectively. The electronic device 1001 may be on a substrate Sub. For example, the lower gate electrode 101 may be on the substrate Sub. Moreover, a part of the ferroelectric layer 201 covering the lower gate electrode 101 may also contact the substrate Sub. Unlike the electronic device 1000 according to the embodiment of FIG. 1, the electronic device 1001 may include a structure in which the ferroelectric layer 201 directly contacts the channel layer 401. That is, the electronic device 1001 may not include a structure such as the first insertion layer 300 of FIG. 1.

Referring to FIG. 1 again, the first insertion layer 300 of the electronic device 1000 may be provided between the ferroelectric layer 200 and the channel layer 400. As described above, the channel layer 401 may include an oxide semiconductor material. There may be a difference in binding energy between the oxygen atoms included in each of the ferroelectric layer 201 and the channel layer 401 including the oxide semiconductor material. When the first insertion layer 300 is not provided between the ferroelectric layer 201 and the channel layer 401, thus allowing the ferroelectric layer 201 and the channel layer 401 to contact each other, in the post deposition annealing (PDA) process, an interaction may occur between the ferroelectric layer 201 and the channel layer 401 due to a difference in binding energy between oxygen atoms of the ferroelectric layer 201 and the channel layer 401. For example, the oxygen atoms of the ferroelectric layer 201 may migrate to and/or from the channel layer 401, creating oxygen vacancies in the ferroelectric layer 201 and/or channel layer 401. The oxygen vacancies may act as traps (e.g., charge-carrier traps) in the ferroelectric layer 201. The interaction may occur during the heating of the electronic device 1000 during some processing steps, and/or during the operation of the device, through charge attractions. Therefore, the interaction between the ferroelectric layer 201 and the channel layer 401 may deteriorate the characteristics of the electronic device 1001.

Referring to FIG. 3, the current-voltage curve of the electronic device 1001 according to a comparative example may exhibit clockwise characteristics. For example, as the value of a gate-source voltage V_{GS} gradually increases in the forward direction at about 0 V, a source-drain current I_{DS} may increase at a predetermined increase rate. When the gate-source voltage V_{GS} gradually increases in the reverse direction at about 4 V, the source-drain current I_{DS} may decrease at a gate-source voltage V_{GS} of higher than 0V at a rate higher than the predetermined increase rate. The hysteretic current-voltage curve of the clockwise characteristic may be evidence that a trap was formed in the electronic device 1001. As described above, a trap may be formed in the electronic device 1001 by the interaction between the ferroelectric layer 201 and the channel layer 401 occurring due to a structure in which the ferroelectric layer 201 directly contacts the channel layer 401.

On the other hand, according to the embodiment shown in FIG. 1, the first insertion layer 300 provided between the ferroelectric layer 200 and the channel layer 400 may suppress the interaction between the ferroelectric layer 200 and the channel layer 400 that may occur in the post deposition annealing (PDA) process. Thus, the formation of a trap may be prevented.

Referring to FIGS. 4 and 5, the current-voltage curve of the electronic device 1000 according to an example embodiment may exhibit counterclockwise characteristics. For example, as the value of a gate-source voltage V_{GS} gradually increases in the forward direction at about 0 V, a source-drain current I_{DS} may increase at a predetermined increase rate. When the gate-source voltage V_{GS} gradually increases in the reverse direction at about 3 V, the source-drain current I_{DS} may decrease at a gate-source voltage V_{GS} of lower than 0V at a rate higher than the predetermined increase rate. The current-voltage curve of the counterclockwise characteristics may be evidence that the ferroelectric expression of the ferroelectric layer 200 of the electronic device 1001 has effectively occurred. As described above, since the first insertion layer 300 provided between the ferroelectric layer 200 and the channel layer 400 may prevent and/or decrease the interaction between the ferroelectric layer 200 and the channel layer 400, the ferroelectric expression of the ferroelectric layer 200 may occur effectively.

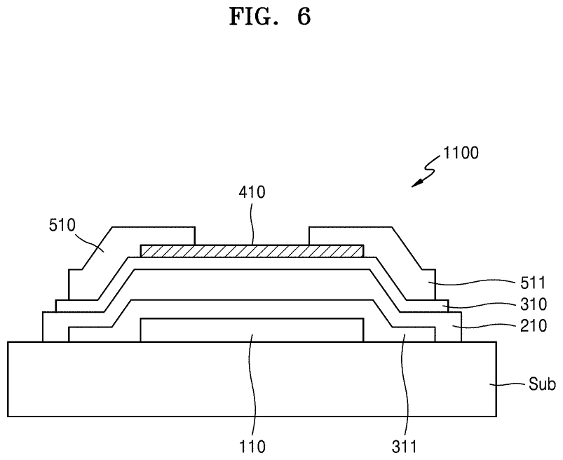

FIG. 6 is a side cross-sectional view schematically illustrating the configuration of an electronic device 1100 according to another embodiment. The electronic device 1100 of FIG. 6 may be substantially the same as the electronic device 1000 of FIG. 1 except for a second insertion layer 311. In the description of FIG. 6, contents overlapping those of FIGS. 1 to 5 will be omitted.

Referring to FIG. 6, the electronic device 1100 may include: a lower gate electrode 110; a ferroelectric layer 210 covering the lower gate electrode 110; a first insertion layer 310 covering the ferroelectric layer 210 and including a dielectric material; a channel layer 410 at a position corresponding to the lower gate electrode 110 on the first insertion layer 310 and including an oxide semiconductor material; and a source electrode 510 and a drain electrode 511 electrically connected to both ends of the channel layer 410, respectively. Meanwhile, the electronic device 1100 may be provided on a substrate Sub. For example, the lower gate electrode 110 may be provided on the substrate Sub. Moreover, a part of the ferroelectric layer 210 may also be contacting the substrate Sub. This electronic device 1100 may be referred to as a bottom gate type transistor.

The electronic device 1100 may further include a second insertion layer 311 provided between the lower gate electrode 110 and the ferroelectric layer 210. The second insertion layer 311 may include a dielectric material. For example, the second insertion layer 311 may include at least one of Al₂O₃, SiOₓ, AlOₓ, SiON, SiN, and/or a combination thereof. For example, the second insertion layer 311 may include at least one of SiO and AlO. The second insertion layer 311 may include a dopant. For example, at least one of Si, Al, Zr, Y, La, Gd, Sr, Hf, and/or Ce may be added as a dopant to at least one of Al₂O₃, SiOₓ, AlOₓ, SiON, and SiN. However, the present invention is not limited thereto, and the type of dopant may include materials other than those listed above. The second insertion layer 311 may also include a dielectric material having insulating properties in addition to the materials listed above. The second insertion layer 311 may comprise the same and/or a different material than the first insertion layer 310

The thickness of the second insertion layer 311 may be equal to the thickness of the ferroelectric layer 210. Alternatively, the second insertion layer 311 may be thinner than the ferroelectric layer 210. For example, the thickness of the second insertion layer 311 may be about 0.3 nm to about 3 nm. The thickness of the first insertion layer 310 and the second insertion layer 311 may be the same and/or different.

The thermal expansion coefficient of the second insertion layer 311 may be different from the thermal expansion coefficient of the ferroelectric layer 210. When a structure in which the second insertion layer 311, the ferroelectric layer 210, and the first insertion layer 310, having different thermal expansion coefficients, is heated, stress based on a difference in the thermal expansion coefficients may be applied to the ferroelectric layer 210 at high temperature. For example, the different thermal expansion coefficient may induce stress in the ferroelectric layer 210 in a domain between the first insertion layer 310 and the second insertion layer 311. The stress may assist in aligning the polarization of the crystalline and/or polycrystalline structure of the ferroelectric layer 210. In this case, the polarization arrangement of the ferroelectric layer 210 is further improved, and domains having the same polarization direction may be formed. For example, a domain of the ferroelectric layer 210 may be compressed by the different thermal expansion coefficients at high temperature, creating a domain of the ferroelectric layer 210 under the channel layer 410 with a different polarization alignment than other domains of the ferroelectric layer 210.

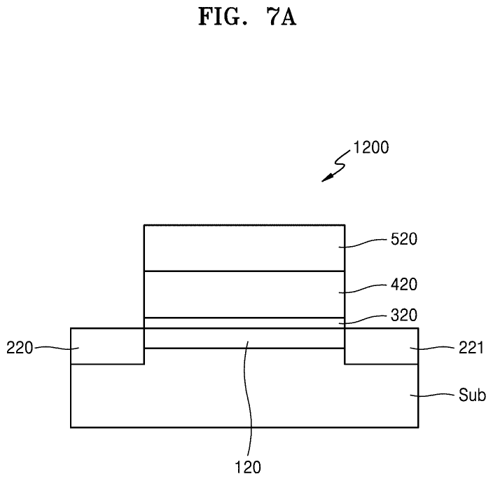

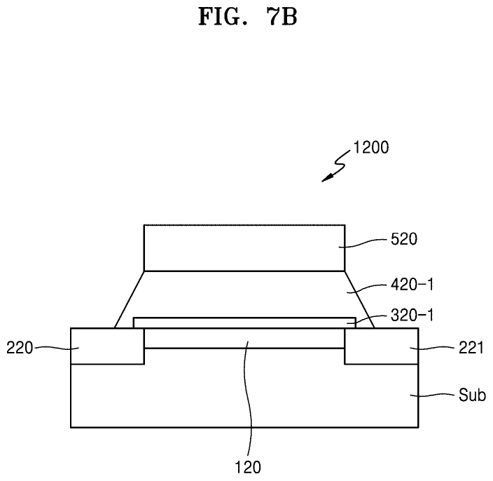

FIGS. 7A and 7B are side cross-sectional views schematically illustrating the configurations of electronic devices 1200 and 1200-1 according to some embodiment. In the description of FIGS. 7A and 7B, contents overlapping those of FIGS. 1 to 5 will be omitted.

Referring to FIGS. 7A and 7B, the electronic devices 1200 and 1200-1 may include: a channel layer 120 including an oxide semiconductor material; a source electrode 220 and a drain electrode 221 formed to be electrically connected to both ends of the channel layer 120, respectively; a first insertion layer 320 and 320-1 covering the channel layer 120 and including a dielectric material; a ferroelectric layer 420 and 420-1 covering the first insertion layer 320 and 320-1, respectively; and a gate electrode 520 covering the ferroelectric layer 420 and 420-1. Meanwhile, the electronic devices 1200 and 1200-1 may be provided on a substrate Sub. For example, the channel layer 120, the source electrode 220, and the drain electrode 221 may be provided on the substrate Sub. The electronic devices 1200 1200-1 may be referred to as a top gate type transistor.

The substrate Sub may include substantially the same material as the substrate Sub of FIG. 1.

The channel layer 120 may include substantially the same material as the channel layer 400 of FIG. 1. For example, the channel layer 120 may include any one oxide semiconductor material of ZnSnO, InGaO, InZnO, InGaZnO, InSnO, InSnZnO, and InSnGaO. The source electrode 220 and the drain electrode 221 may include substantially the same material as the source electrode 500 and the drain electrode 501 of FIG. 1.

The first insertion layer 320 may include substantially the same material as the first insertion layer 300 of FIG. 1. For example, the first insertion layer 320 may include at least one of Al₂O₃, SiOₓ, AlOₓ, SiON, SiN, and/or a combination thereof. The source electrode 220 and drain electrode 221 may border the first insertion layer 320, as illustrated in FIG. 7A or the first insertion layer 320-1 may partially overlap the source electrode 220 and drain electrode 221 as illustrated in FIG. 7B.

The thickness of the first insertion layer 320 may be equal to the thickness of the ferroelectric layer 420. Alternatively, the first insertion layer 320 may be thinner than the ferroelectric layer 420. For example, the thickness of the first insertion layer 320 may be about 0.3 nm to about 3 nm.

The thermal expansion coefficient of the first insertion layer 320 may be different from the thermal expansion coefficient of the ferroelectric layer 420. Like this, when a structure in which the first insertion layer 320 and the ferroelectric layer 420, having different thermal expansion coefficients, are stacked is heated, stress based on a difference in thermal expansion coefficient may be applied to the ferroelectric layer 420 at high temperature. In this case, the polarization arrangement of the ferroelectric layer 420 is further improved, and domains having the same polarization direction may be formed. For example, stress may be induced in a domain of the ferroelectric layer 210 above the channel layer 120 by the different thermal expansion coefficients at high temperature, creating a domain of the ferroelectric layer 420 over the channel layer 120 with a different polarization alignment than other domains of the ferroelectric layer 420. For example the other domains may include regions of the ferroelectric layer 420-1 extending past the channel layer 120 in a first direction, parallel to the direction in which the source electrode 220 and the drain electrode 221 are spaced, as depicted in FIG. 7B, and/or regions of the ferroelectric layer 420 extending in a second direction, in the same plane and perpendicular to the first direction.

The ferroelectric layer 420 may include substantially the same material as the ferroelectric layer 200 of FIG. 1. For example, the ferroelectric layer 420 may include at least one of HfO, ZrO, SiO, AIO, CeO, YO, LaO, and a perovskite structure compound. Moreover, the ferroelectric layer 420 may include a dopant. For example, at least one of Si, Al, Zr, Y, La, Gd, Sr, Hf, and Ce may be added to the at least one of HfO, ZrO, SiO, AlO, CeO, YO, LaO, and a perovskite structure compound. The footprint the ferroelectric layer 420 may be substantially similar to an upper surface of the first insertion layer 320, as illustrated in FIG. 7A, or the foot print of the ferroelectric layer 420-1 may extend past the first insertion layer 320-1, as illustrated in FIG. 7B.

The gate electrode 520 may include substantially the same material as the lower gate electrode 100 of FIG. 1. For example, the gate electrode 520 may include a metal material such as molybdenum (Mo), titanium (Ti), tantalum (Ta), tungsten (W), aluminum (Al), copper (Cu), neodymium (Nd), or scandium (Sc). In addition, the gate electrode 520 may include nitride of the aforementioned metal material, or may include an alloy material including the aforementioned metal material as a main ingredient.

The first insertion layer 320 may be provided between the ferroelectric layer 420 and the channel layer 120. As described above, the channel layer 120 may include an oxide semiconductor material. When the first insertion layer 320 is not provided between the ferroelectric layer 420 and the channel layer 120, thus allowing the ferroelectric layer 420 and the channel layer 120 to contact each other, in the post deposition annealing (PDA) process, a specific interaction may occur between the ferroelectric layer 420 and the channel layer 120. The interaction between the ferroelectric layer 420 and the channel layer 120 may deteriorate the characteristics of the electronic device 1200. For example, a trap may be formed according to the interaction between the ferroelectric layer 420 and the channel layer 120.

However, according to the embodiment shown in FIGS. 7A and 7B, the first insertion layer 320 provided between the ferroelectric layer 420 and the channel layer 120 may suppress and/or prevent the interaction between the ferroelectric layer 420 and the channel layer 120 that may occur in the post deposition annealing (PDA) process. Thus, the formation of a trap may be suppressed and/or prevented.

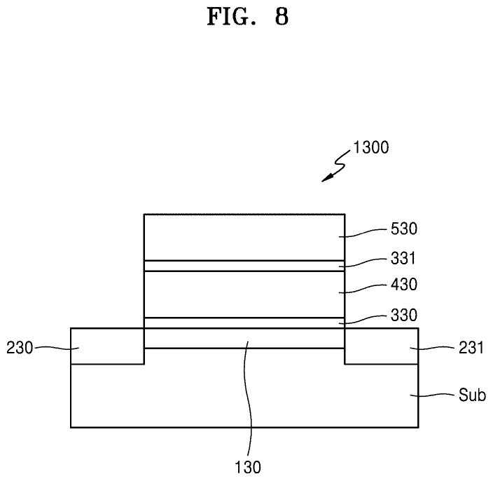

FIG. 8 is a side cross-sectional view schematically illustrating the configuration of an electronic device 1300 according to another embodiment. The electronic device 1300 of FIG. 8 may have substantially the same configuration as the electronic device 1200 of FIG. 7A except for a second insertion layer 331. In the description of FIG. 8, contents overlapping those of FIGS. 7A and/or 7B will be omitted.

Referring to FIG. 8, the electronic device 1300 may include: a channel layer 130 including an oxide semiconductor material; a source electrode 230 and a drain electrode 231 formed to be electrically connected to both ends of the channel layer 130, respectively; a first insertion layer 330 covering the channel layer 130 and including a dielectric material; a ferroelectric layer 430 covering the first insertion layer 330; and a gate electrode 530 covering the ferroelectric layer 430. Meanwhile, the electronic device 1300 may be on a substrate Sub. For example, the channel layer 130, the source electrode 230, and the drain electrode 231 may be on the substrate Sub. This electronic device 1300 may be referred to as a top gate type transistor.

The electronic device 1300 may further include a second insertion layer 331 provided between the ferroelectric layer 430 and the gate electrode 530. The second insertion layer 331 may include a dielectric material. For example, the second insertion layer 331 may include at least one of Al₂O₃, SiOₓ, AlOₓ, SiON, SiN, and/or a combination thereof. For example, the second insertion layer 331 may include at least one of SiO and AlO. The second insertion layer 331 may include a dopant, such as at least one of Si, Al, Zr, Y, La, Gd, Sr, Hf, and/or Ce added to the at least one of Al₂O₃, SiOₓ, AlOₓ, SiON, and SiN. However, the present invention is not limited thereto. For example, the type of dopant may include materials other than those listed above, and the second insertion layer 331 may include a dielectric material having insulating properties in addition to the materials listed above. The first insertion layer 330 and the second insertion layer 331 may also include the same and/or different materials.

The thickness of the second insertion layer 331 may be equal to the thickness of the ferroelectric layer 430. Alternatively, the second insertion layer 331 may be thinner than the ferroelectric layer 430. For example, the thickness of the second insertion layer 331 may be about 0.3 nm to about 3 nm. The thickness of the first insertion layer 330 and the second insertion layer 331 may be the same and/or different.

The thermal expansion coefficient of the second insertion layer 331 may be different from the thermal expansion coefficient of the ferroelectric layer 430. When the second insertion layer 331, the ferroelectric layer 430, and the first insertion layer 330, having different thermal expansion coefficients, are heated, stress based on a difference in thermal expansion coefficient may be applied to the ferroelectric layer 430 at high temperature. For example, the different thermal expansion coefficient may induce stress in the ferroelectric layer 430 in a domain between the first insertion layer 330 and the second insertion layer 331 due to strain resulting from the different thermal expansions. The stress may assist in aligning the polarization of the crystalline and/or polycrystalline structure of the ferroelectric layer 430. In this case, the polarization arrangement of the ferroelectric layer 430 may be further improved, and domains having the same polarization direction may be formed.

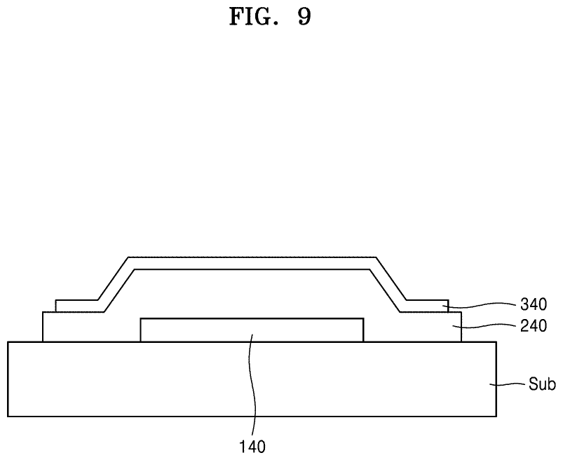

FIGS. 9 to 11 are side cross-sectional views schematically illustrating the procedure of a method of manufacturing an electronic device 1400 according to an example embodiment. Since contents for materials included in a substrate Sub, a lower gate electrode 140, a ferroelectric layer 240, a first insertion layer 340, a channel layer 440, a source electrode 540 and a drain electrode 541, shown in FIGS. 9 to 11, are substantially the same as those having been described with reference to FIGS. 1 to 5, the contents will be omitted.

Referring to FIG. 9, the method of manufacturing an electronic device 1400 includes: forming a lower gate electrode 140 on a substrate Sub; forming a ferroelectric layer 240 covering the lower gate electrode 140; and forming a first insertion layer 340 covering the ferroelectric layer 240. In the forming of the ferroelectric layer 240 and the first insertion layer 340, the ferroelectric layer 240 and the first insertion layer 340 may be continuously formed in the same chamber without changing formation conditions. The forming conditions may be, for example, pressure, temperature, and the like in the chamber. As described above, when the ferroelectric layer 240 and the first insertion layer 340 are continuously formed in the same process step, the expression of ferroelectricity of the ferroelectric layer 240 may occur more effectively. Moreover, since the ferroelectric layer 240 and the first insertion layer 340 are formed in the same process step, the manufacturing process of the electronic device 1400 may be simplified, and the manufacturing cost thereof may be reduced.

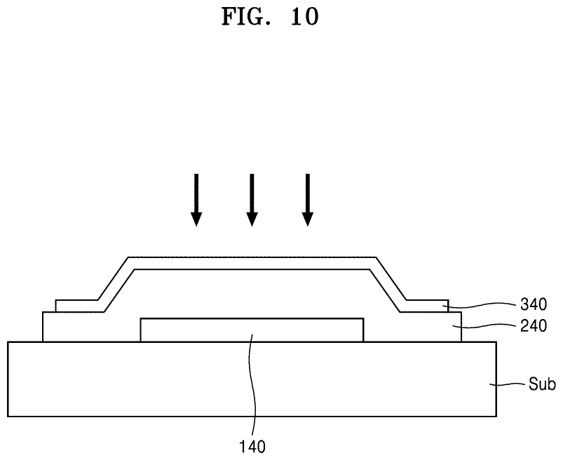

Referring to FIG. 10, the method of manufacturing the electronic device 1400 may further include: performing heat treatment on the ferroelectric layer 240 and the first insertion layer 340. Through this heat treatment, the crystal phase of the material included in the ferroelectric layer 240 may be changed. For example, the ferroelectric layer 240 may be crystallized by heat treatment at a high temperature of 600° C. or higher to have ferroelectricity.

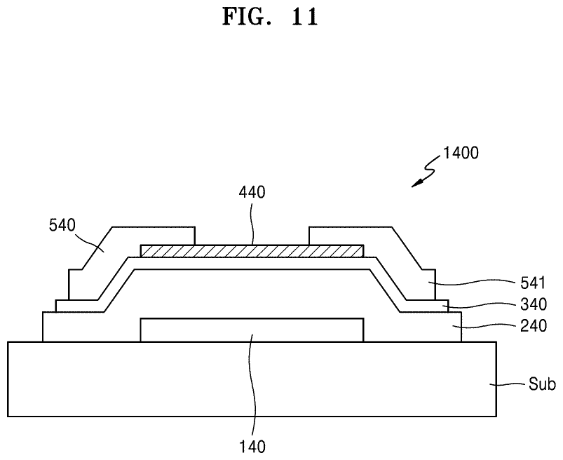

Referring to FIG. 11, the method of manufacturing the electronic device 1400 may further include: forming a channel layer 440 including an oxide semiconductor material on the first insertion layer 340 at a position corresponding to the lower gate electrode 140; and forming a source electrode 540 and a drain electrode 541 to be electrically connected to each end of the channel layer 440, respectively.

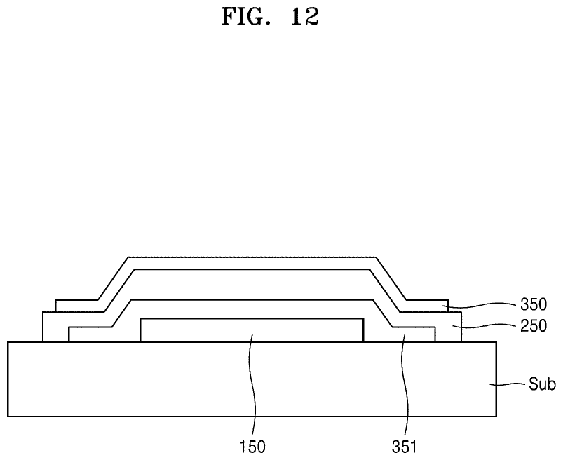

FIGS. 12 to 14 are side cross-sectional views schematically illustrating the procedure of a method of manufacturing an electronic device 1500 according to another example embodiment. Since contents for materials included in a substrate Sub, a lower gate electrode 150, a ferroelectric layer 250, a first insertion layer 350, a second insertion layer 351, a channel layer 450, a source electrode 550 and a drain electrode 551, shown in FIGS. 12 to 14, are substantially the same as those having been described with reference to FIGS. 1 to 5 and 6, the contents will be omitted.

Referring to FIG. 12, the method of manufacturing an electronic device 1500 includes: forming a lower gate electrode 150 on a substrate Sub; and forming a ferroelectric layer 250 covering the lower gate electrode 150; forming a first insertion layer 350 covering the ferroelectric layer 250. The method of manufacturing an electronic device 1500 may further include: forming a second insertion layer 351 covering the lower gate electrode 150 after forming the gate electrode 150 but before the forming of the ferroelectric layer 250. The second insertion layer 351, the ferroelectric layer 250, and the first insertion layer 350 may be sequentially and continuously formed. For example, the second insertion layer 351, the ferroelectric layer 250, and the first insertion layer 350, the second insertion layer 351, the ferroelectric layer 250, and the first insertion layer 350 may be formed in the same chamber without changing formation conditions. The forming conditions may be, for example, pressure, temperature, and the like in the chamber. As described above, when the second insertion layer 351, the ferroelectric layer 250, and the first insertion layer 350 are continuously formed in the same process step, the expression of ferroelectricity of the ferroelectric layer 250 may occur more effectively. Moreover, since the second insertion layer 351, the ferroelectric layer 250, and the first insertion layer 350 are continuously formed in the same process step, the manufacturing process of the electronic device 1500 may be simplified, and the manufacturing cost thereof may be reduced.

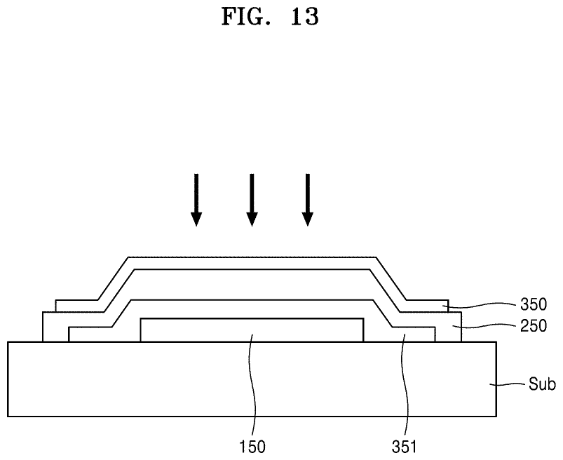

Referring to FIG. 13, the method of manufacturing the electronic device 1500 may further include: performing heat treatment on the second insertion layer 351, the ferroelectric layer 250, and the first insertion layer 350.

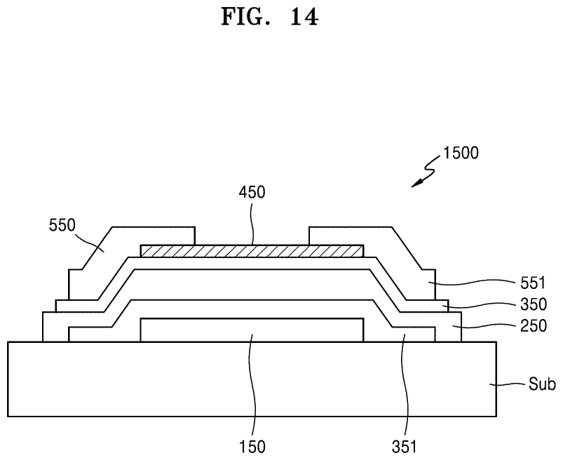

Referring to FIG. 14, the method of manufacturing the electronic device 1500 may further include: forming a channel layer 450 including an oxide semiconductor material on the first insertion layer 350 at a position corresponding to the lower gate electrode 150; and forming a source electrode 550 and a drain electrode 551 to be electrically connected to each end of the channel layer 450, respectively.

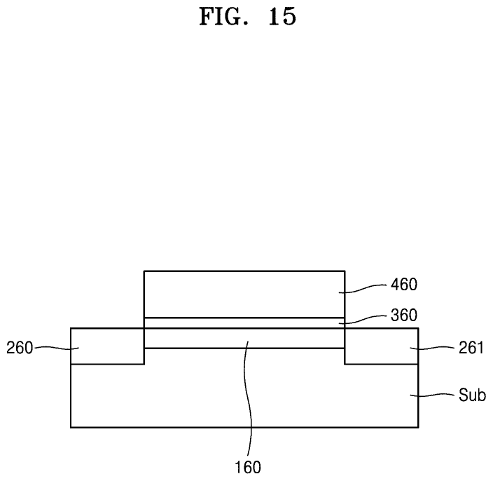

FIGS. 15 to 17 are side cross-sectional views schematically illustrating the procedure of a method of manufacturing an electronic device 1600 according to an embodiment. Since contents for materials included in a substrate Sub, a channel layer 160, a source electrode 260, a drain electrode 261, a first insertion layer 360, a ferroelectric layer 460, and a gate electrode 560, shown in FIGS. 15 to 17, are substantially the same as those having been described with reference to FIG. 7\ the contents will be omitted.

Referring to FIG. 15, the method of manufacturing an electronic device 1600 includes: forming a channel layer 160 including an oxide semiconductor material and a source electrode 260 and a drain electrode 261 electrically connected to both ends of the channel layer 160 on a substrate Sub, respectively; forming a first insertion layer 360 covering the channel layer 160; and forming a ferroelectric layer 460 covering the first insertion layer 360. The first insertion layer 360 and the ferroelectric layer 460, may be continuously formed in the same chamber without changing formation conditions. The forming conditions may be, for example, pressure, temperature, and the like in the chamber. As described above, when the first insertion layer 360 and the ferroelectric layer 460 are continuously formed in the same process step, the expression of ferroelectricity of the ferroelectric layer 460 may occur more effectively. Moreover, since the first insertion layer 360 and the ferroelectric layer 460 are continuously formed in the same process step, the manufacturing process of the electronic device 1600 may be simplified, and the manufacturing cost thereof may be reduced. The formation of the first insertion layer 360 may be grown on the channel layer 160, with the oxide semiconductor included in the channel layer 160 acting as a seed and aggregation layer for the first insertion layer 360. The first insertion layer 360 may also include a section of overgrowth partially overlapping the source electrode 260 and the drain electrode 261. Similarly, the ferroelectric layer 460 may be formed on the first insertion layer 360, with the first insertion layer 360 acting as a seed and/or aggregation layer for the formation of the ferroelectric layer 460. Alternatively, the first insertion layer 360 and the ferroelectric layer 460 may be deposited onto the channel layer using a shadow mask and/or etched to remove access material. The etching of the first insertion layer 360 and the ferroelectric layer 460 may, however, be done in a separate process, for example after the heat treatment described below.

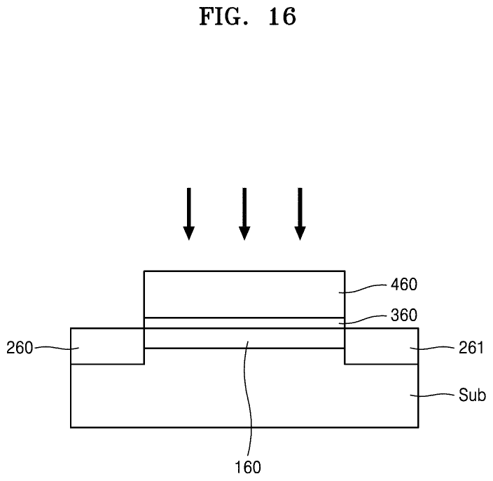

Referring to FIG. 16, the method of manufacturing the electronic device 1600 may further include: performing heat treatment on the first insertion layer 360 and the ferroelectric layer 460. Through this heat treatment, the crystal phase of the material included in the ferroelectric layer 460 may be changed. For example, the ferroelectric layer 460 may be crystallized by heat treatment at a high temperature of 600° C. or higher to have ferroelectricity.

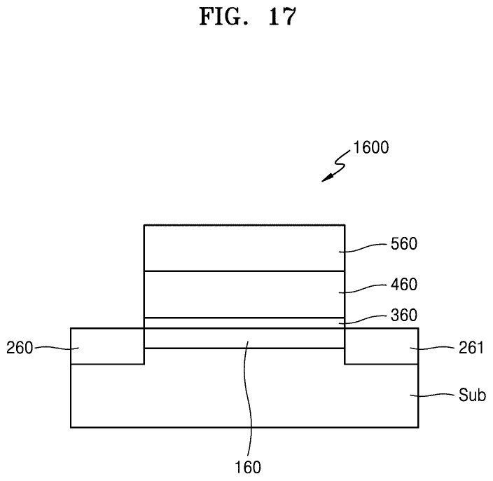

Referring to FIG. 17, the method of manufacturing an electronic device 1600 may further include: forming a gate electrode 560 covering the ferroelectric layer 460.

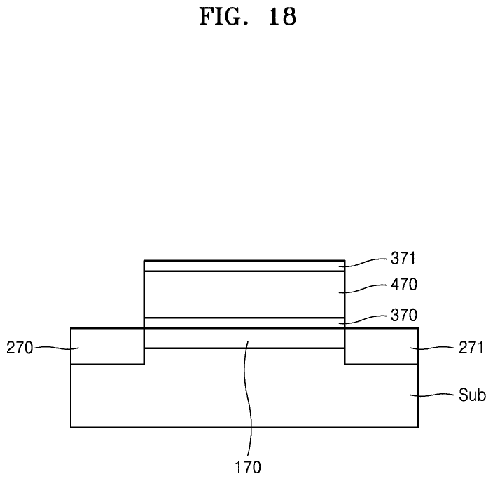

FIGS. 18 to 20 are side cross-sectional views schematically illustrating the procedure of a method of manufacturing an electronic device 1700 according to an example embodiment. Since contents for materials included in a substrate Sub, a channel layer 170, a source electrode 270, a drain electrode 271, a first insertion layer 370, a second insertion layer 371, a ferroelectric layer 470, and a gate electrode 570, shown in FIGS. 18 to 20, are substantially the same as those having been described with reference to FIGS. 7 and 8, the contents will be omitted.

Referring to FIG. 18, the method of manufacturing an electronic device 1700 includes: forming a channel layer 170 including an oxide semiconductor material and a source electrode 270 and a drain electrode 271 electrically connected to both ends of the channel layer 170 on a substrate Sub, respectively; forming a first insertion layer 370 covering the channel layer 170; and forming a ferroelectric layer 470 covering the first insertion layer 370. The method of manufacturing an electronic device 1700 may further include: forming a second insertion layer 371 covering the ferroelectric layer 470 and including a dielectric layer after forming the ferroelectric layer 470. The first insertion layer 370, the ferroelectric layer 470, and the second insertion layer 371 may be sequentially and continuously formed. The forming of the first insertion layer 370, the ferroelectric layer 470, and the second insertion layer 371 may be continuously formed in the same chamber without changing formation conditions. The forming conditions may be, for example, pressure, temperature, and the like in the chamber. As described above, when the first insertion layer 370, the ferroelectric layer 470, and the second insertion layer 371 are continuously formed in the same process step, the expression of ferroelectricity of the ferroelectric layer 470 may occur more effectively. Moreover, since the first insertion layer 370, the ferroelectric layer 470, and the second insertion layer 371 are continuously formed in the same process step, the manufacturing process of the electronic device 1700 may be simplified, and the manufacturing cost thereof may be reduced.

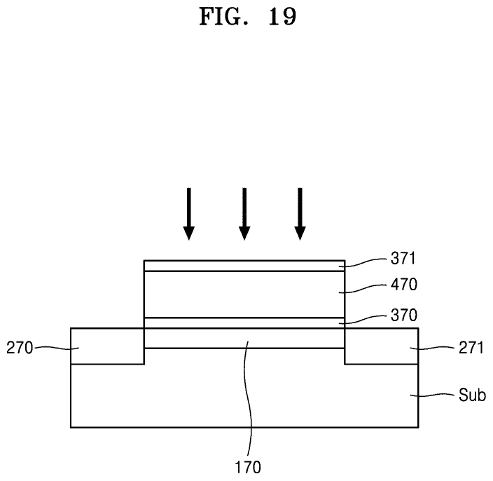

Referring to FIG. 19, the method of manufacturing the electronic device 1700 may further include: performing heat treatment on the first insertion layer 370, the ferroelectric layer 470, and the second insertion layer 371. Through this heat treatment, the crystal phase of the material included in the ferroelectric layer 470 may be changed. For example, the ferroelectric layer 470 may be crystallized by heat treatment at a high temperature of 600° C. or higher to have ferroelectricity.

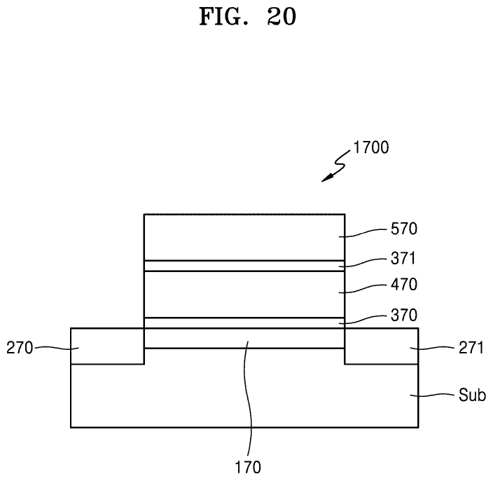

Referring to FIG. 20, the method of manufacturing the electronic device 1700 may include: forming a gate electrode 570 covering the second insertion layer 371.

The aforementioned electronic devices including a ferroelectric layer and a first insertion layer 330 may be applied to various electronic circuit devices including a transistor, for example as part of processing circuity and/or memory.

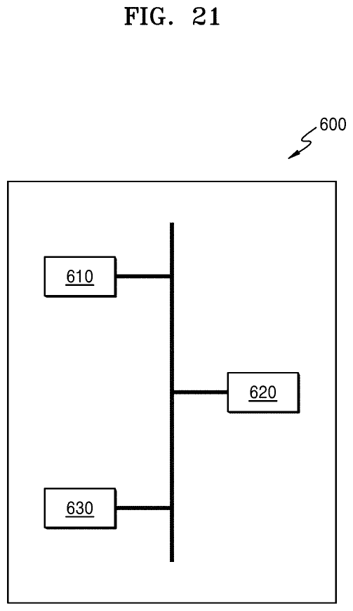

FIG. 21 shows a schematic of a circuit device that may include the aforementioned semiconductor devices according to some example embodiments.

As shown, the electronic device 600 includes one or more electronic device components, including a processor (e.g., processing circuitry) 610 and a memory 620 that are communicatively coupled together via a bus 640.

The processing circuitry 610, may be included in, may include, and/or may be implemented by one or more instances of processing circuitry such as hardware including logic circuits, a hardware/software combination such as a processor executing software; or a combination thereof. For example, the processing circuitry 600 may include, but is not limited to, a central processing unit (CPU), an application processor (AP), an arithmetic logic unit (ALU), a graphic processing unit (GPU), a digital signal processor, a microcomputer, a field programmable gate array (FPGA), a System-on-Chip (SoC) a programmable logic unit, a microprocessor, or an application-specific integrated circuit (ASIC), etc. In some example embodiments, the memory 620 may include a non-transitory computer readable storage device, for example a solid state drive (SSD), storing a program of instructions, and the processing circuitry 600 may be configured to execute the program of instructions to implement the functionality of the electronic device 600.

In some example embodiments, the electronic device 600 may include one or more additional components 630, coupled to bus 640, which may include, for example, a power supply, a light sensor, a light-emitting device, any combination thereof, or the like. In some example embodiments, one or more of the processing circuitry 610, memory 620, and/or one or more additional components 630 may include any electronic device including an oxide semiconductor channel layer, source and drain electrodes, a ferroelectric layer, a first insertion layer between channel layer and the ferroelectric layer, and a gate electrode according to any of the example embodiments described herein, such that the one or more of the processing circuitry 610, memory 620, and/or one or more additional components 630, and thus, the electronic device 600, may include the electronic device 1000 (refer to FIG. 1).

According to an example embodiment of the present disclosure, an insertion layer including a dielectric material may be provided between a ferroelectric layer and a channel layer including an oxide semiconductor material, thereby reducing an interaction between the ferroelectric layer and the channel layer.

According to an example embodiment of the present disclosure, a ferroelectric layer and an insertion layer may be continuously formed, thereby enhancing ferroelectricity of the ferroelectric layer and reducing a process cost.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An electronic device comprising:
a lower gate electrode;
a ferroelectric layer covering the lower gate electrode;
a first insertion layer covering the ferroelectric layer, the first insertion layer including a dielectric material;
a channel layer on the first insertion layer, at a position corresponding to the lower gate electrode, the channel layer including an oxide semiconductor material; and
a source electrode electrically connected to a first end of the channel layer and a drain electrode electrically connected to a second end of the channel layer.

2. The electronic device of claim 1, wherein the first insertion layer is thinner than the ferroelectric layer.

3. The electronic device of claim 1, wherein the first insertion layer has a thickness of about 0.3 nm to about 3 nm.

4. The electronic device of claim 1, wherein a thermal expansion coefficient of the first insertion layer is different from a thermal expansion coefficient of the ferroelectric layer.

5. The electronic device of claim 1, wherein the first insertion layer includes at least one of Al₂O₃, SiOₓ, AlOₓ, SiON, SiN, and a combination thereof.

6. The electronic device of claim 1, wherein the oxide semiconductor material includes at least one of ZnSnO, InGaO, InZnO, InGaZnO, InSnO, InSnZnO, and InSnGaO.

7. The electronic device of claim 1, wherein the ferroelectric layer includes a HfO₂-based dielectric material.

8. The electronic device of claim 1, wherein the ferroelectric layer includes a domain under the channel layer with a polarization alignment different from another domain of the ferroelectric layer.

9. The electronic device of claim 1, further comprising a second insertion layer provided between the lower gate electrode and the ferroelectric layer, the second insertion layer including a dielectric material.

10. The electronic device of claim 9, wherein the second insertion layer is thinner than the ferroelectric layer.

11. The electronic device of claim 9, wherein the second insertion layer has a thickness of about 0.3 nm to about 3 nm.

12. An electronic device comprising:
a channel layer including an oxide semiconductor material;
a source electrode and a drain electrode electrically connected to a first end and a second end of the channel layer, respectively;
a first insertion layer covering the channel layer, the first insertion layer including a dielectric material;
a ferroelectric layer covering the first insertion layer; and
a gate electrode covering the ferroelectric layer.

13. The electronic device of claim 12, wherein the first insertion layer is thinner than the ferroelectric layer.

14. The electronic device of claim 12, wherein the first insertion layer has a thickness of about 0.3 nm to about 3 nm.

15. The electronic device of claim 12, further comprising: a second insertion layer provided between the ferroelectric layer and the gate electrode and including a dielectric material.

16. The electronic device of claim 15, wherein the second insertion layer is thinner than the ferroelectric layer.

17. The electronic device of claim 15, wherein the second insertion layer has a thickness of about 0.3 nm to about 3 nm.

18. A method of manufacturing an electronic device, the method comprising:
forming a lower gate electrode on a substrate;
continuously forming a ferroelectric layer and a first insertion layer, the ferroelectric layer covering the lower gate electrode and the first insertion layer covering the ferroelectric layer, the first insertion layer including a dielectric material;
forming a channel layer on the first insertion layer at a position corresponding to the lower gate electrode, the channel layer including an oxide semiconductor material; and
forming a source electrode and a drain electrode to be electrically connected to a first end and a second end of the channel layer, respectively.

19. The method of claim 18, wherein, in the continuous forming of the ferroelectric layer and the first insertion layer, the ferroelectric layer and the first insertion layer are continuously formed in the same chamber without changing formation conditions.

20. The method of claim 18, wherein the first insertion layer is formed to a thickness of about 0.3 nm to about 3 nm.

21. The method of claim 18, further comprising forming a second insertion layer before the ferroelectric layer, the second insertion layer covering the lower gate electrode and including a dielectric material,
wherein the second insertion layer, the ferroelectric layer, and the first insertion layer are sequentially and continuously formed.

22. A method of manufacturing an electronic device, the method comprising:
forming, on a substrate, a channel layer including an oxide semiconductor material and a source electrode and a drain electrode electrically connected to a first end and a second end of the channel layer, respectively;
continuously forming a first insertion layer and a ferroelectric layer, the first insertion layer covering the channel layer and including a dielectric material and a ferroelectric layer covering the first insertion layer; and
forming a gate electrode covering the ferroelectric layer.

23. The method of claim 22, wherein, in the continuously forming the first insertion layer and the ferroelectric layer, the first insertion layer and the ferroelectric layer are continuously formed in the same chamber without changing formation conditions.

24. The method of claim 22, wherein the first insertion layer is formed to a thickness of about 0.3 nm to about 3 nm.

25. The method of claim 22, further comprising forming a second insertion layer covering the ferroelectric layer before forming the gate electrode, the second insertion layer including a dielectric material,
wherein the first insertion layer, the ferroelectric layer, and the second insertion layer are sequentially and continuously formed.
